(19) United States
(12) Patent Application Publication
(10) Pub. No.: US 2009/0031954 A1
(43) Pub. Date: Feb. 5, 2009

(54) SUSCEPTOR AND APPARATUS FOR MANUFACTURING EPITAXIAL WAFER

(76) Inventors: Kouichi Nishikido, Nagasaki (JP); Motonori Nakamura, Nagasaki (JP); Atsuhiko Hirosawa, Kanagawa (JP); Noboru Iida, Kanagawa (JP); Norihiko Sato, Kanagawa (JP); Atsushi Nagato, Kanagawa (JP); Toshiyuki Kamei, Kanagawa (JP)

Correspondence Address: FRISHAUF, HOLTZ, GOODMAN & CHICK, PC, 220 Fifth Avenue, 16TH Floor, NEW YORK, NY, 10001-7708, US

(21) Appl. No.: 12/278,650

(22) PCT Filed: Feb. 8, 2007
(86) PCT No.: PCT/JP2007/052225

§ 371 Date: Aug. 7, 2008

(30) Foreign Application Priority Data
Feb. 9, 2006 (JP) 2006-032878

(51) Int. Cl. C23C 16/00

(52) U.S. Cl. 118/725; 118/728

(57) ABSTRACT

A susceptor capable of reducing unevenness in a film-thickness of an epitaxial film on an outer surface of a substrate wafer and a manufacturing apparatus of an epitaxial wafer are provided. The susceptor includes a wafer placement and a peripheral portion. The wafer placement is greater in size than the substrate wafer W and substantially disc-shaped. The peripheral portion is substantially in a ring-plate shape and includes: an inner circumference standing in a fashion surrounding a peripheral portion of the wafer placement; and an upper surface outwardly extending from an upper end of the inner circumference in parallel to the placement surface of the wafer placement. In the chemical vapor deposition control unit, an inner circumference has a curvature substantially similar to a curvature of the inner circumference of the peripheral portion, and the upper surface is leveled with the upper surface) of the peripheral portion. The chemical vapor deposition control unit is made of SiO2 which is less reactive with a reaction gas than a SiC film.

### TECHNICAL FIELD

The present invention relates to a susceptor and a manufacturing apparatus of an epitaxial wafer.

### BACKGROUND ART

In recent years, as high integration of semiconductors proceeds, reduction of to crystalline defects of semiconductors, particularly reduction of crystalline defects on a surface of a semiconductor and crystalline defects near a surface of a semiconductor, is becoming important. Accordingly, demand for an epitaxial wafer on which an epitaxial film excellent in crystallinity is chemically vapor deposited is increasing year by year.

A manufacturing method of such an epitaxial wafer has been disclosed in, for example, Patent Document 1.

According to the manufacturing method of the epitaxial wafer disclosed in Patent Document 1, a surface of a susceptor is provided with a spot facing portion for holding a semiconductor crystal substrate (hereafter abbreviated to substrate).

A dimension from an upper surface of the substrate to the surface of the susceptor with the substrate held on the spot facing portion is defined as a difference h. An optimal value of the difference h (hereafter an optimal difference h0) at which an average deposition rate of a single crystal thin film at a periphery of the substrate is about the same as an average deposition rate at a central portion of the single crystal thin film is obtained.

A depth D0 of the spot facing portion is temporarily determined by a sum of the thickness d of the substrate and the optimal difference h0.

Patent Document 1: JP-A-2003-12397 (page 2, right column to page 5, left column)

### DISCLOSURE OF THE INVENTION

### Problems to be Solved by the Invention

According to the arrangement in Patent Document 1, when an epitaxial wafer is manufactured under a determined condition, a chemical vapor deposition rate (hereafter abbreviated to CVD rate) at a bevel portion of a substrate wafer where the crystal orientation is (100) is faster than a CVD rate at a bevel portion where the crystal orientation is (110), so that absorption at the bevel portion in which the crystal orientation is (100) is greater. Here, the absorption at the bevel portion possibly includes absorption of a reaction gas above an outer surface of a surface and absorption of a growing epitaxial film from the outer circumferential portion of the surface. If the reaction gas is absorbed, the reaction gas delivered to the outer circumferential portion of the surface decreases, so that the film-thickness of the outer circumferential portion of the surface decreases. If the growing epitaxial film is absorbed, the film-thickness of the outer circumferential portion of the surface decreases likewise.

As a result, even if film-thickness distribution toward a periphery of the outer circumferential portion of the surface where the crystal orientation is (100) is substantially uniform, a film-thickness of the outer circumferential portion of the surface where the crystal orientation is (110) decreases toward a periphery.

An object of the present invention is to provide a susceptor that can reduce unevenness in film-thickness of an epitaxial film at an outer circumferential portion of a surface of a substrate wafer and a manufacturing apparatus of an epitaxial wafer.

### Means for Solving the Problems

The susceptor according to an aspect of the present invention is a susceptor on which a substrate wafer is placed when an epitaxial wafer is manufactured by growing an epitaxial film by chemical vapor deposition on a surface of the substrate wafer, the susceptor including: a wafer placement on which the substrate wafer is placed; a peripheral portion provided in a fashion surrounding a periphery of the wafer placement; and a chemical vapor deposition control unit that is provided to at least a portion of the peripheral portion and controls a chemical vapor deposition rate at a bevel portion and an outer surface of the substrate wafer placed on the wafer placement.

Here, the relationship between the chemical vapor deposition control unit (hereafter occasionally abbreviated to CVD control unit), which is provided on at least a portion of the peripheral portion, and the crystal orientation of the substrate wafer, which is placed on the wafer placement, is important. A chemical vapor deposition rate (hereafter occasionally abbreviated to CVD rate) of an epitaxial film at the bevel portion of the substrate wafer differs in accordance with the crystal orientation. Therefore, the above-mentioned object is achieved by suppressing or promoting chemical vapor deposition that corresponds to the crystal orientation. More specifically, the crystal orientation of the substrate wafer affects the CVD rate at the bevel portion of the outer surface, and the difference in the CVD rates thereof causes unevenness in film-thickness distribution. Consequently, chemical vapor deposition control that promotes chemical vapor deposition is conducted at a thin portion of the film, and chemical vapor deposition control that suppresses chemical vapor deposition is conducted at a thick portion of the film. Thus, evenness in the film-thickness distribution can be provided.

The CVD control unit may be made of a material different from a material that forms the peripheral portion or a material different from a material that forms the wafer placement, or may be formed in an external shape distinguished from the peripheral portion or the wafer placement using the same material.

According to the aspect of the invention, at least a portion of the peripheral portion of the wafer placement is provided with the CVD control unit for controlling the CVD rate at the bevel portion and the outer surface of the substrate wafer to be placed on the wafer placement, that is, the edge portion of the substrate wafer (hereafter referred to as the water edge). Thus, the CVD rate at the wafer edge of the substrate wafer near the CVD control unit is controlled to be different from the other portions. Accordingly, the film-thickness distribution in the peripheral direction at the outer surface of the wafer edge near the CVD control unit can be different from a film-thickness distribution of the case without the CVD control unit.

Therefore, the film-thickness distribution at the outer surface can be made, irrespective of the crystal orientation, substantially even, so that the unevenness in the film-thickness at the outer surface can be reduced.

In the above arrangement, the peripheral portion preferably comprises an inner circumference standing in a fashion surrounding the wafer placement and an upper surface outwardly extending from an upper end of the inner circumference in parallel to a placement surface of the wafer placement, and the chemical vapor deposition control unit preferably is provided to at least one of the inner circumference and the upper surface at the portion of the peripheral portion and made of a material that promotes or suppresses reaction with a reaction gas for growing the epitaxial film by chemical vapor deposition.

With this arrangement, the peripheral portion includes the inner circumference standing in a fashion surrounding the water placement and the upper surface outwardly extending from the upper end of the inner circumference in parallel to the placement surface of the wafer placement. At least one of the portion in the upper surface and the portion in the inner circumference of the peripheral portion is provided with the CVD control unit made of a material that promotes or suppresses reaction with a reaction gas.

For example, if the CVD control unit is made of a material that promotes reaction with a reaction gas, the following function allows the CVD rate at the bevel portion near the CVD control unit to be slower than in the case without the CVD) control unit.

That is, a relatively large amount of the reaction gas delivered near the CVD control unit reacts with the CVD control unit, so that little of the reaction gas is flowed to the wafer edge near the CVD control unit.

On the other hand, if such a CVD control unit is not provided, a portion of the reaction gas delivered to the peripheral portion is flowed to the wafer edge. In other words, less reaction gas is delivered to the wafer edge in the case with the CVD control unit than in the case without it. Since the reaction gas is significantly caught by the CVD control unit, as set forth above, the CVD rate at the bevel portion near the CVD control unit can be decreased compared to the case without the CVD control unit.

Accordingly, by increasing the absorption at the bevel portion near the CVD control unit, the film-thickness at the outer peripheral side of the outer surface near the CVD control unit can be controlled to be thinner compared to the case without the CVD control unit.

Furthermore, for example, if the CVD control unit is made of a material that suppresses reaction with a reaction gas, the following function allows the CVD rate at the bevel portion near the CVD control unit to be faster compared to the case without the CVD control unit.

That is, a relatively large amount of the reaction gas delivered near the CVD control unit does not react with the CVD control unit, thereby flowing to the wafer edge near the CVD control unit.

On the other hand, if such a CVD control unit is not provided, a portion of the reaction gas delivered to the peripheral portion is flowed to the wafer edge. In other words, more reaction gas is delivered to the wafer edge compared to the case without the CVD control unit. Thus, the reaction gas resides without reacting with the CVD control unit, so that the reaction gas concentration at the wafer edge increases. Consequently, the CVD rate of the bevel portion near the CVD control unit can be made faster compared to the case without the CVD control unit, as set forth above.

Accordingly, by decreasing the absorption at the bevel portion near the CVD control unit, the film-thickness at the outer peripheral side of the outer surface near the CVD control unit is controlled to be thicker compared to the case without the CVD control unit.

Therefore, by only forming the CVD control unit from a material that promotes or suppresses reaction with a reaction gas, the film-thickness distribution at the outer surface can be made, irrespective of the crystal orientation, substantially even, so that the unevenness in the film-thickness at the outer surface can be reduced.

In the above arrangements, the chemical vapor deposition control unit preferably comprises an inner circumference that has a curvature substantially similar to a curvature of the inner circumference of the peripheral portion and an upper surface that is leveled with the upper surface of the peripheral portion, and at least a portion of the inner circumference of the chemical vapor deposition control unit preferably projects toward a placement center of the wafer placement compared to other portions of the inner circumference of the peripheral portion.

With this arrangement the inner circumference of the CVD control unit projects toward the placement center of the wafer placement compared to other portions of the inner circumference of the peripheral portion. Accordingly, the following advantage can be obtained compared to the arrangement of the susceptor in which a distance between an inner circumference of the CVD control unit and the center of the wafer placement is the same as distances between the inner circumferences of other portions of the peripheral portion and the center of the wafer placement. That is, reaction gas delivered to the CVD control unit and flowed toward the wafer edge is ensured to reach the wafer edge. Therefore, unevenness in the film-thickness at the outer surface can be efficiently reduced.

A susceptor according to another aspect of the present invention is a susceptor on which a substrate wafer is placed when an epitaxial wafer is manufactured by chemical vapor deposition of an epitaxial film on a surface of the substrate wafer, the susceptor including: a wafer placement on which the substrate wafer is placed; a peripheral portion that comprises an inner circumference standing in a fashion surrounding the wafer placement and an upper surface outwardly extending from an upper end of the inner circumference along a placement surface of the wafer placement; and a chemical vapor deposition control unit that is formed on the peripheral portion, the chemical vapor deposition control unit comprising a wide section and a narrow section respectively having a different length from a center of the wafer placement in an outward direction, and being made of a material that promotes or suppresses reaction with a reaction gas for growing the epitaxial film by chemical vapor deposition.

The susceptor according to the aspect of the present invention is provided with the CVD control unit on the peripheral portion. The CVD control unit includes a wide section and a narrow section having a different length from a center of the wafer placement in an outward direction. The CVD control unit is made of a material in which reaction with a reaction gas is promoted or suppressed.

If the CVD control unit is made of a material that promotes reaction with a reaction gas, less reaction gas is delivered to the wide section of the CVD control unit and flowed toward the wafer edge than is delivered to the narrow section of the CVD control unit and flowed toward the wafer edge.

Thus, the CVD rate at the bevel portion near the wide section is controlled to be slower than that at the bevel portion near the narrow section. Accordingly, absorption at the bevel portion near the wide section increases. As a result, the film-thickness at an outer peripheral side of the outer surface near the wide section is controlled to be thinner than that near the narrow section.

On the other hand, if the CVD control unit is made of a material that suppresses reaction with a reaction gas, more reaction gas is delivered to the wide section and flowed toward the wafer edge than is delivered to the narrow section and flowed toward the wafer edge.

Thus, the CVD rate of the bevel portion near the wide section is controlled to be faster than that of the bevel portion near the narrow section. Accordingly, absorption at the bevel portion near the wide section decreases. As a result, the film-thickness of an outer peripheral side of the outer surface near the wide section is controlled to be thicker than that near the narrow section.

Therefore, the film-thickness distribution at the outer surface can be made substantially even irrespective of the crystal orientation, so that the unevenness of the film-thickness at the outer surface can be reduced.

In the above arrangements, the chemical vapor deposition control unit preferably is formed as a member made of the material and fitted to the peripheral portion.

With this arrangement, the durability of the substrate wafer in the etching process can be improved compared to an arrangement in which the CVD control unit is formed as a thin film.

Therefore, a longer period of usage is afforded compared to the arrangement in which the CVD control unit is provided as a thin film.

In the above arrangements, the chemical vapor deposition control unit preferably is provided in such manner that the material that promotes or suppresses reaction with the reaction gas is exposed in a discrete pattern.

With this arrangement, the material forming the CVD control unit that promotes or suppresses reaction with the reaction gas is exposed in a discrete pattern. Accordingly, when a silicon film is formed on a predetermined portion of the CVD control unit, the formed film is hindered from spreading over the entire CVD control unit, compared to an arrangement in which the material is exposed in a continuous pattern.

Therefore, compared to the arrangement in which the CVD control unit is exposed in a continuous pattern, the CVD control unit can be used for a longer time without, for example, removal process of the silicon film.

In the above arrangements, the chemical vapor deposition control unit preferably is formed as a low-flatness section having a larger surface area per unit region than other portions of the upper surface of the peripheral portion.

Here, the unit region refers to a regional area having, for example, a rectangular or annular shape, defined by predetermined dimensions. The large surface area per unit region corresponds to a low flatness of the unit region. For example, when portions of the upper surface of the peripheral portion other than the CVD control unit are flat, the CVD control unit having a large surface area per unit region is formed in a rough surface having greater irregularities than the other portions of the upper surface.

With this arrangement, the CVD control unit provided in the form of a low-flatness section having a larger surface area per unit region than that of the other portions of the upper surface. Thus, a reaction gas is more likely to be adsorbed to the low-flatness section than to the other portions (hereafter referred to as the high-flatness section). Accordingly, more reaction gas is delivered to the high-flatness section and flowed toward the wafer edge than is delivered to the low-flatness section and flowed toward the wafer edge.

Thus, the CVD rate at the bevel portion near the high-flatness section is controlled to be faster than that at the bevel portion near the low-flatness section. Accordingly, absorption at the bevel portion near the high-flatness section decreases. As a result, the film-thickness of an outer peripheral side of the outer surface near the high-flatness section is controlled to be thicker than that near the low-flatness section. Therefore, the film-thickness distribution at the outer surface can be made substantially even irrespective of the crystal orientation, so that the unevenness of the film-thickness at the outer surface can be reduced.

In the above arrangements, the peripheral portion preferably comprises a periphery body having an upper surface formed substantially in a ring shape that is leveled with the wafer placement and a projection projecting upward from a portion of the upper surface of the periphery body, and the chemical vapor deposition control unit preferably is a portion of the periphery body excluding the projection and is formed in such manner that a side of the substrate wafer is exposed when the substrate wafer is placed on the wafer placement.

With this arrangement, more reaction gas is delivered to the CVD control unit at the peripheral portion and flowed toward the wafer edge than is delivered to the projection and flowed toward the wafer edge.

Thus, the CVD rate at the bevel portion near the CVD control unit is faster than that at the bevel portion near the projection. Accordingly, absorption at the bevel portion near the CVD control unit is decreased. Therefore, the film-thickness at the outer surface near the CVD control unit is controlled to be thicker than that near the projection. Therefore, the film-thickness distribution at the outer surface can be made substantially even irrespective of the crystal orientation, so that the unevenness of the film-thickness at the outer surface can be reduced.

In the above arrangements, the chemical vapor deposition control unit is provided in a manner corresponding to the crystal orientation of the substrate wafer placed on the wafer placement.

With this arrangement, since the CVD control unit is provided in a manner corresponding to the crystal orientation of the substrate wafer, unevenness in the film-thickness at the outer surface on account of the crystal orientation is reduced.

A manufacturing apparatus of an epitaxial wafer according to another aspect of the present invention is a manufacturing apparatus of an epitaxial wafer that manufactures an epitaxial wafer by growing an epitaxial film by chemical vapor deposition on a surface of the substrate wafer, the manufacturing apparatus including: the susceptor according to any one of claims 1 to 9; a reaction container in which the susceptor is housed and into which a reaction gas for growing the epitaxial film by chemical vapor deposition on the surface of the substrate wafer can be delivered; and a heater that heats substrate wafer upon growing the epitaxial film by chemical vapor deposition.

In the aspect of the present invention, the manufacturing apparatus of the epitaxial wafer employs the susceptor with the functions and effects set forth above.

Accordingly, the manufacturing apparatus of an epitaxial wafer capable of manufacturing an epitaxial wafer with reduced unevenness in film-thickness at am outer surface thereof can be provided.

### BRIEF DESCRIPTION OF DRAWINGS

FIG. 1 is a cross-sectional view schematically showing a manufacturing apparatus of an epitaxial wafer according to a first embodiment of the present invention.

FIG. 2A is a top view schematically showing a susceptor according to the first embodiment.

FIG. 2B is a cross-sectional view taken along B-B line in FIG. 2A.

FIG. 2C is a cross-sectional view taken along C-C line in FIG. 2A.

FIG. 3 is a top view of susceptors in Examples 1, 2, and 3 used for experiments to describe function of the manufacturing apparatus of an epitaxial wafer.

FIG. 4 shows a first wafer edge and a film-thickness distribution of an epitaxial film in a case of an epitaxial wafer manufactured using the susceptor in Example 1.

FIG. 5 is a top view of a susceptor in Comparative Example used in experiments to describe function of the manufacturing apparatus of an epitaxial wafer.

FIG. 6 shows a first wafer edge and a film-thickness distribution of an epitaxial film in a case of an epitaxial wafer manufactured using the susceptor in Comparative Example.

FIG. 7 is a graph showing a film-thickness change ratio at a variety of notch-referenced angles of an epitaxial wafer manufactured using the susceptor in Example 1.

FIG. 8 is a graph showing a film-thickness change ratio at a variety of notch-referenced angles of an epitaxial wafer manufactured using the susceptor in Example 2.

FIG. 9 is a graph showing a film-thickness change ratio at a variety of notch-referenced angles of an epitaxial wafer manufactured using the susceptor in Example 3.

FIG. 10 is a graph showing a film-thickness change ratio at a variety of notch-referenced angles of an epitaxial wafer manufactured using the susceptor in Comparative Example.

FIG. 11A is a top view schematically showing a susceptor according to a second embodiment of the present invention.

FIG. 11B is a cross-sectional view taken along B-B line in FIG. 11A.

FIG. 11C is a cross-sectional view taken along C-C line in FIG. 11A.

FIG. 12 is a view showing a height of an inner periphery relative to an upper surface of the periphery body at a variety of notch-opposition-referenced angles in the second embodiment.

FIG. 13 is a top view schematically showing a susceptor according to a third embodiment of the present invention.

FIG. 14 is a top view schematically showing a susceptor according to a fourth embodiment of the present invention.

FIG. 15 is a top view schematically showing a susceptor according to a fifth embodiment of the present invention.

FIG. 16 is a top view schematically showing a susceptor according to a sixth embodiment of the present invention.

FIG. 17 is a top view schematically showing a susceptor according to a seventh embodiment of the present invention.

### EXPLANATION OF CODES

1 . . . manufacturing apparatus
2, 500, 510, 520, 800, 810, 820, 830, 840, 850 . . . susceptor
3 . . . reaction container
4 . . . heater
21 . . . wafer placement
21A . . . placement surface
22, 502, 512, 522, 802, 812, 822, 832, 842, 852 . . . peripheral portion
22A, 502A, 512A, 522A, 812A, 822A, 832A, 842A, 852A . . . inner circumference
22B, 502B, 512B, 522B, 812B, 822B, 832B, 842B, 852B . . . upper surface
23, 503, 513, 523, 805, 813, 833A, 833B, 833C . . . chemical vapor deposition control unit (CVD control unit)
23A . . . inner circumference
23B . . . upper surface
803 . . . periphery body
804 . . . projection
842D . . . low-flatness section
W . . . substrate water
WE₁₀₁ . . . bevel portion
WE₁₀₂ . . . outer surface
EP . . . epitaxial film
EPW . . . epitaxial wafer

### BEST MODE FOR CARRYING OUT THE INVENTION

### First Embodiment

A first embodiment of the present invention will be described below with reference to the drawings.

(Arrangement of Manufacturing Apparatus of Epitaxial Wafer)

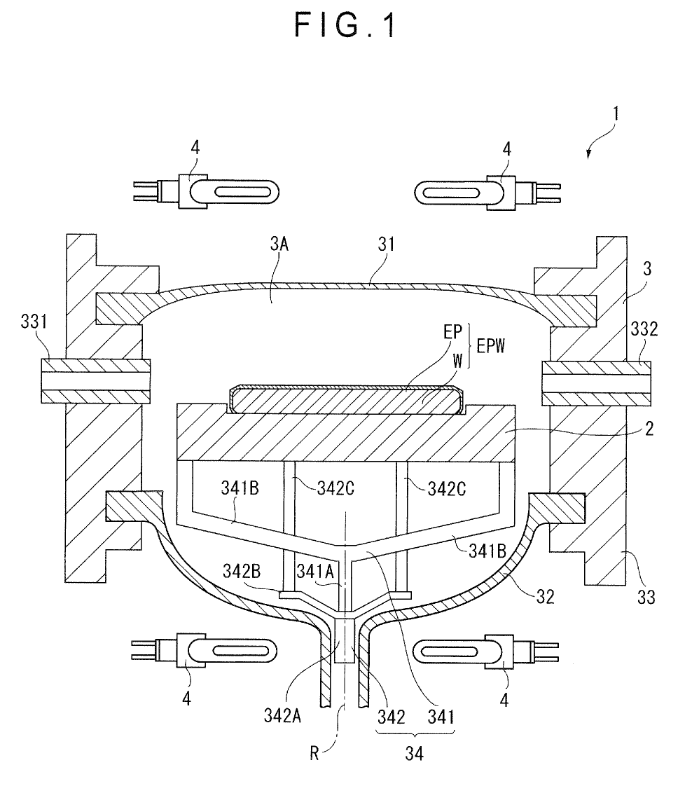

FIG. 1 is a cross-sectional view schematically showing a manufacturing apparatus 1 of an epitaxial water.

The manufacturing apparatus 1 is a sheet type manufacturing apparatus that manufactures an epitaxial wafer EPW by vapor depositing an epitaxial film EP on a substrate wafer W The manufacturing machine 1 is arranged to manufacture an epitaxial wafer EPW having a diameter of 200 mm. Incidentally, the manufacturing apparatus 1 may be arranged to manufacture an epitaxial wafer EPW having a diameter of more than 200 mm. As shown in FIG. 1, the manufacturing apparatus 1 includes a susceptor 2, a reaction container 3, and a heater 4.

Note that an outer surface in the first embodiment and second to seventh embodiments described below is an area including a peripheral edge and a region within 5 mm from the peripheral edge of the substrate wafer W. Also note that the outer surface of substrate wafers, irrespective of diameters thereof, is not limited to the above-mentioned area, but may mean, for example, a region within 1 mm or a region within 7 mm from the periphery.

The susceptor 2 is, as specifically described below, a member on which the substrate wafer W is placed, which is installed inside the reaction container 3

The reaction container 3 houses the susceptor 2 and is so arranged that a reaction gas can be delivered inside the reaction container 3. The reaction gas is delivered to the substrate wafer W placed on the susceptor 2, so that the epitaxial film EP is chemically vapor deposited on a surface of the substrate wafer W. As shown in FIG. 1, the reaction container 3 includes an upper dome 31, a lower dome 32, a dome mount 33, and a susceptor-supporter 34.

The upper dome 31 and the lower dome 32 are made of a translucent material such as quartz or the like and shaped as domes respectively outwardly expanding at substantially central portions thereof.

The dome mount 33 is formed of a substantially cylindrical member having an opened top, which supports the upper dome 31, and an opened bottom, which supports the lower dome 32. As shown in FIG. 1 a reaction chamber 3A is formed within the reaction container 3 by mounting the upper dome 31 and the lower dome 32 to the dome mount 33.

As shown in FIG. 1, a reaction gas feed pipe 331 and a reaction gas discharge pipe 332 are provided to lateral sides of the dome mount 33. The reaction gas feed pipe 331 and the reaction gas discharge pipe 332 intercommunicate the reaction chamber 3A and the exterior of the reaction container 3

The reaction gas feed pipe 331 and the reaction gas discharge pipe 332 are disposed opposite to each other at an upper portion of the reaction container 3. According to the arrangement set forth above, when reaction gas is delivered to the interior of the reaction chamber 3A from the exterior of the reaction container 3 via the reaction gas feed pipe 331, the reaction gas is horizontally flowed over an upper surface of the substrate wafer W on the susceptor 2 supported by the susceptor-supporter 34, and the reaction gas and the like in the reaction chamber 3A are discharged to the exterior of the reaction container 3 via the reaction gas discharge pipe 332.

Here, the reaction gas may be a mixture of a source gas containing silicon atoms for chemical vapor deposition of an epitaxial film EP and a carrier gas. The source gas is employed in accordance with the epitaxial film EP to be chemically vapor deposited. For example, SiHCl₃ for a silicon source and B₂H₆ for a boron dopant source may be diluted by a hydrogen gas to form a mixture reaction gas. The carrier gas may contain, or example, hydrogen.

The susceptor-supporter 34 is made of a translucent material such as quartz or the like and projects into the reaction chamber 3A from a substantially central portion of the lower dome 32 of the reaction container 3. The susceptor 2 is horizontally placed in the reaction container 3 by the susceptor-supporter 34. The placement of the wafer on the susceptor 2 is also afforded by the susceptor-supporter 34. The susceptor-supporter 34 is, for example, rotated about a rotation axis R by an external controller (not shown). As shown in FIG. 1, the susceptor-supporter 34 includes a susceptor-supporter body 341 and a wafer lift 342.

The susceptor-supporter body 341 includes: a base portion 341A projecting into the reaction chamber 3A from the substantially central portion of the lower dome 32; three extending portions 341B extending in the reaction chamber 3A toward the inner lateral sides of the dome mount 33 from the upper end of the base portion 341A. The three extending portions 341B of the susceptor-supporter body 341 have distal ends extending upward. The distal ends support a periphery of a lower surface of the susceptor 2 at three points. The susceptor-supporter body 341 supports the susceptor 2 to allow horizontal placement of the susceptor 2 in the reaction chamber 3A.

Incidentally, the shape of the susceptor-supporter body 341 is not limited to the above description. The extending portions 341B may be more than three. The extending portions 341B may be formed in a circle in plan view, radially spreading from the upper end of the base portion 341A.

The wafer lift 342 includes: a base portion 342A formed in a cylinder surrounding a base end portion of the susceptor-supporter 34, three extending portions 342B extending in the reaction chamber 3A toward the inner lateral sides of the dome mount 33 from an upper end of the base portion 342A; and three pin-like members 342C attached to the distal ends of the three extending portions and extending upward.

The wafer lift 342 is rotatable about the rotation axis R and vertically movable with respect to the susceptor-supporter body 341. A vertical movement of the wafer lift 342 causes a distal end of the pin-like member 342C to abut to the substrate wafer W via a to below-described pin insertion hole 21B of the susceptor 2, thereby vertically moving the substrate wafer W.

More specifically, according to the embodiment, a loading method between a conveying jig (not shown) that conveys a wafer to and from the manufacturing apparatus 1 and the susceptor 2 is as follows. The loading of a wafer is conducted by advancement and retraction of the wafer lift 342 while a lower surface of the wafer is supported by the pin-like member 342C.

Incidentally, the wafer lift 342 may be omitted. In this case, the wafer may be loaded to the susceptor 2 from the conveying jig, which conveys the wafer to and from the manufacturing apparatus 1, by employing Verneuil chuck or by lifting and lowering the conveying jig.

Each of the heaters 4 is respectively provided to an upper side and lower side of the reaction container 3. The substrate wafer W placed on the susceptor 2 and the susceptor 2 are heated by the heaters 4 with radiation heat via the upper dome 31 and the lower dome 32 of the reaction container 3 to set the temperature of the substrate wafer W at a predetermined value. The heater 4 may be, for example, a halogen lamp, an infrared lamp, or the like. Incidentally, the heater 4 may be a high-frequency heater that heats the substrate wafer W with induction heating as well as the heater that heats with radiation heat.

(Arrangement of Susceptor)

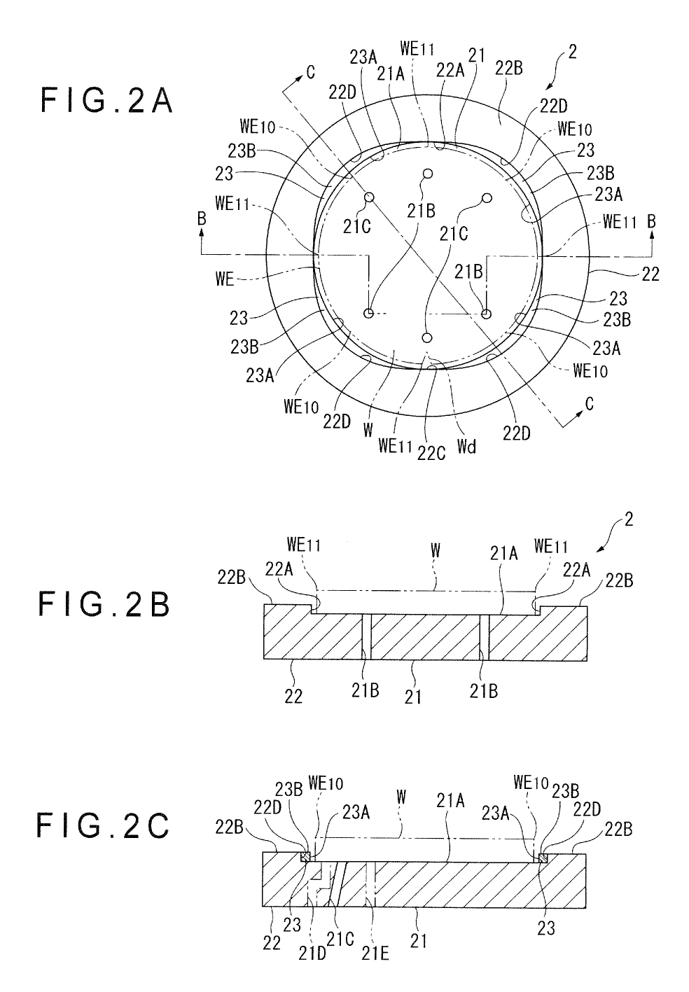

FIGS. 2A to 2C schematically show an arrangement of the susceptor 2. FIG. 2A is a top view of the susceptor 2. FIG. 2B is a cross-sectional view taken along B-B line in FIG. 2A. FIG. 2C is a cross-sectional view taken along C-C line in FIG. 2A.

As shown in FIG. 2A, the susceptor 2, for example, is made of a carbon-based material, is substantially disc-shaped possessing a larger size than the substrate wafer W, and includes a wafer placement 21 that has a placement surface 21A on which the substrate wafer W is placed.

Here, the wafer edge WE of the substrate wafer W includes a first wafer edge WE₁₀ where crystal orientation is (100) and a second wafer edge WE₁₁ where crystal orientation is (110). The first wafer edge WE₁₀ and the second wafer edge WE₁₁ are alternately provided approximately every 45° in a circumferential direction. The first wafer edge WE₁₀ is located where notch-referenced angles thereof are 45°, 135°, 225°, and 315°. Here and hereafter, the notch-referenced angle is a counter-clockwise angle relative to a notch Wd formed on the wafer edge WE. The second wafer edge WE₁₁ is located where the notch-referenced angles are 0°, 90°, 180°, and 270°.

As shown in FIGS. 2A and 2B, the wafer placement 21 includes the three pin insertion holes 21B through which the pin-like members 342C of the wafer lift 342 forming the susceptor-supporter 34 are insertable. As shown in FIGS. 2A and 2C, the wafer placement 21 also includes three ventilation apertures 21C whose axes intersect with the vertical direction.

Incidentally, the ventilation apertures 21C may be substituted by ventilation apertures 21D that contain a substantially axially horizontal portion substantially at vertical center thereof or ventilation apertures 21E having substantially vertical axes.

The substrate wafer W is placed on the wafer placement 21 in a manner that the center of the substrate wafer W substantially aligns with the center of the wafer placement 21 and the notch Wd is constantly located at a predetermined position. The substrate wafer W in such a state will be referred to as a placement-determined state.

Further, the wafer placement 21 is integrally provided with a peripheral portion 22 substantially in a ring-plate shape. The peripheral portion 22 includes: an inner circumference 22A standing in a fashion surrounding a peripheral portion of the wafer placement 21; and an upper surface 22B outwardly extending from an upper end of the inner circumference 22A in parallel to the placement surface 21A of the wafer placement 21.

At least the inner circumference 22A and the upper surface 22B of the peripheral portion 22 are coated by, for example, a SiC film. In addition, fitting grooves 22D are formed at portions of the inner circumference of the peripheral portion 22 where notch-opposition-referenced angles are 45°, 135°, 225°, and 315°. Here and hereafter, the notch-opposition-referenced angle is a counter-clockwise angle relative to a notch-opposing portion 22C facing the notch Wd of the substrate wafer W in the placement-determined state. The fitting groove 22D is substantially falcate in plan view. A substantially central portion relative to an arc direction of the fitting groove 22D is located near each of the above-mentioned portions of the inner circumference of the peripheral portion 22. In other words, the peripheral portion 22 is provided with the fitting grooves 22D at locations opposite to the first wafer edge WE₁₀ of the substrate wafer W but is not provided with fitting grooves at locations opposite to the second wafer edge WE₁₁.

Incidentally, if the substrate wafer W to be placed has the first wafer edge WE₁₀ at portions where the notch-referenced angles are 0°, 90°, 180°, and 270°, the fitting grooves 22D are formed at locations where the notch-opposition-referenced angles are 0°, 90°, 180°, and 270°.

A chemical vapor deposition control unit (hereafter abbreviated to CVD control unit) 23 is attached to the fitting groove 22D. The CVD control unit 23 is a member made of quarts, i.e. SiO₂, which is less reactive to a reaction gas than SiC. The CVD control unit 23 is substantially falcate in plan view corresponding to the shape of the fitting groove 22D. In other words, the CVD control unit 23 is attached to the fitting groove 22D in a fashion that an inner circumference 23A thereof has a curvature substantially similar to a curvature of the inner circumference 22A of the peripheral portion 22 and the upper surface 23B is leveled with the upper surface 22B of the peripheral portion 22. In the CVD control unit 23, the upper surface 23B is leveled with the upper surface 22B for the greatest length at portions where the notch-opposition-referenced angles are 45°, 135°, 225°, and 315°. The length for which the upper surface 23B is leveled with the upper surface 22B becomes gradually shorter as the location becomes farther from the above-mentioned portions.

Incidentally, a material that forms the CVD control unit 23 is not limited to SiO₂, but may be other materials less reactive to a reaction gas than SiC, such as SiN and the like.

(Operation of Manufacturing Apparatus of Epitaxial Wafer)

Next, operation of the manufacturing apparatus 1 will be described with reference to a manufacturing process of the epitaxial wafer EPW.

Initially, the conveying jig (not shown) is moved while the pin-like members 342C of the wafer lift 342 is advanced and retrieved according to the above-described loading method of a wafer, so that the substrate wafer W is placed on the wafer placement 21 in the placement-determined state. Here, a high-accuracy position confirmation sensor (not shown) is preferably attached to the conveying jig to ensure that the substrate wafer W is placed in the placement-determined state.

H₂ gas is delivered via the reaction gas feed pipe 331 into the reaction chamber 3A heated to a high temperature by the heater 4, and a native oxidation film on a surface of the substrate wafer W is removed by high-temperature gas etching.

Subsequently, an epitaxial film EP is chemically vapor deposited on the substrate wafer W, as described below.

Firstly, the substrate wafer W is heated by the heater 4 to a desirable growth temperature.

Secondly, while the susceptor-supporter 34 is rotated about the rotation axis R, a reaction gas is horizontally delivered on the surface of the substrate wafer W via the reaction gas feed pipe 331. As such a chemical vapor deposition is conducted, an epitaxial film EP is formed on the surface of the substrate wafer W to yield the epitaxial wafer EPW.

(Operation of Manufacturing Apparatus of Epitaxial Wafer)

Next, function of the manufacturing apparatus 1 of an epitaxial wafer EPW will be described.

Hereafter, film-thickness change ratio will be employed in the description, which is a value obtained by subtracting a film-thickness at a location 95 mm apart from the center of the epitaxial wafer EPW from each of film-thicknesses at locations 96 mm, 97 mm, 98 mm, and 99 mm apart from the center of the epitaxial wafer EPW and dividing the calculated differences by the film-thickness at a location 95 mm apart from the center of the epitaxial wafer EPW.

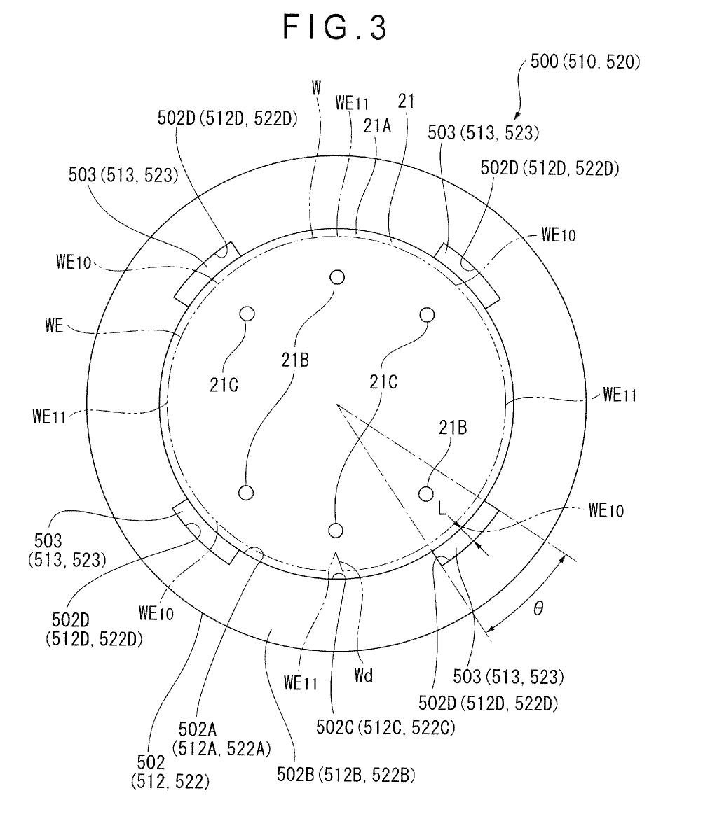

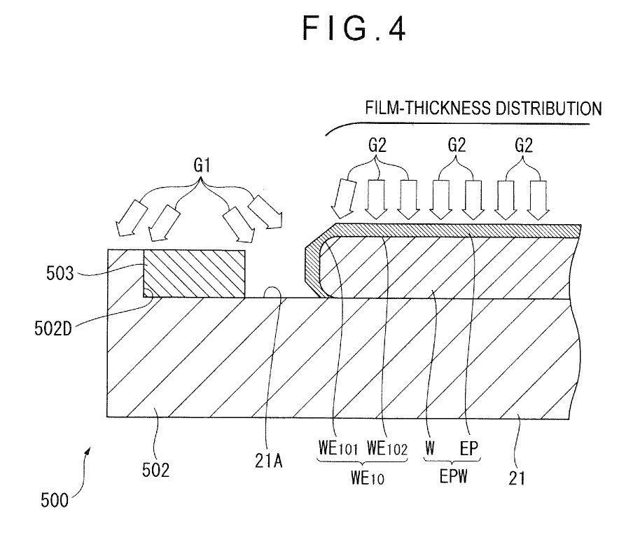

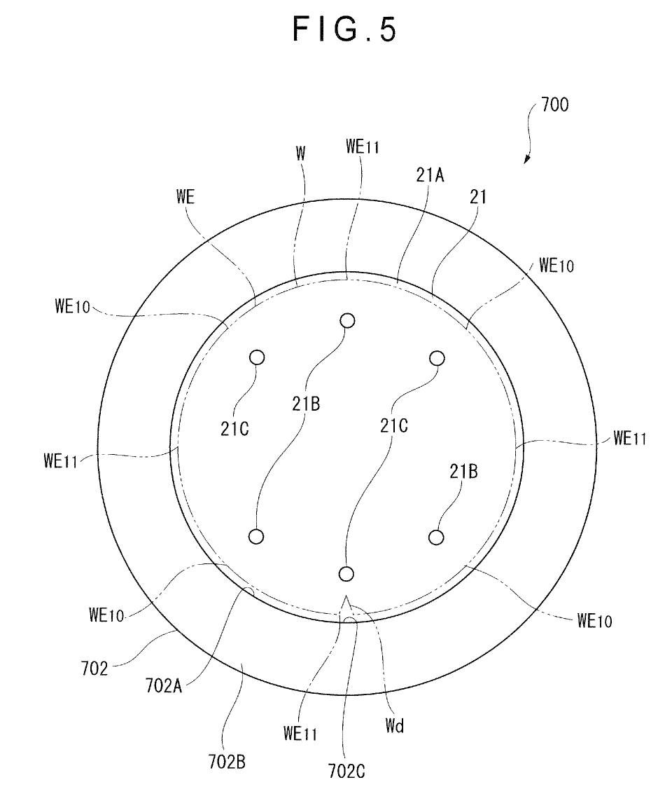

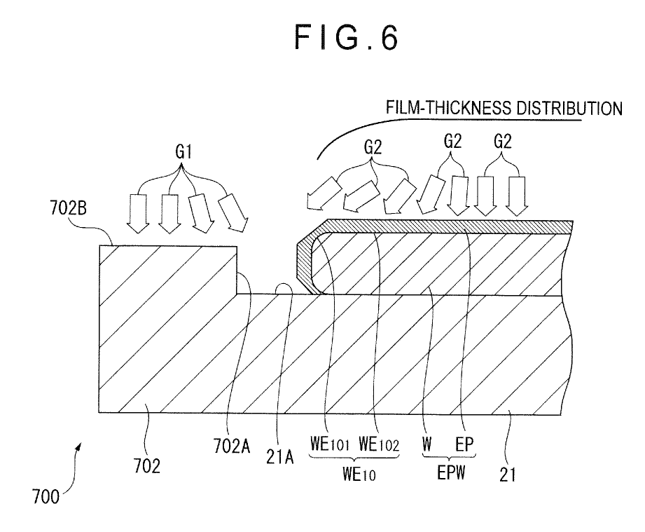

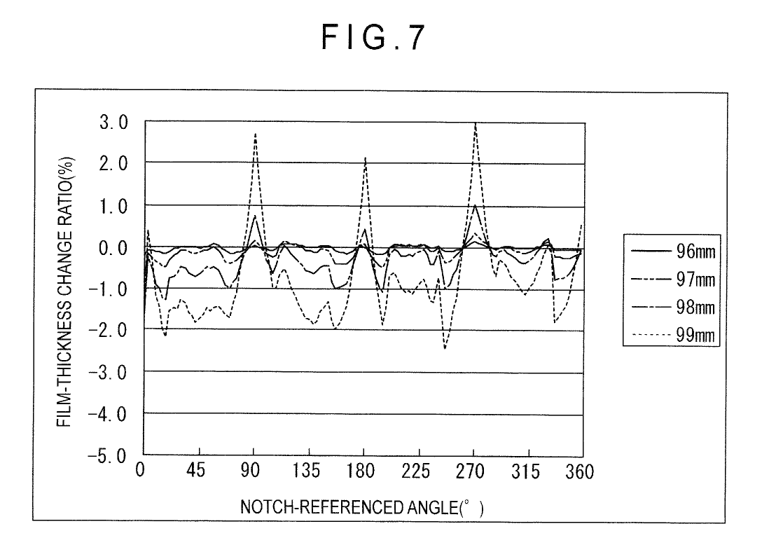

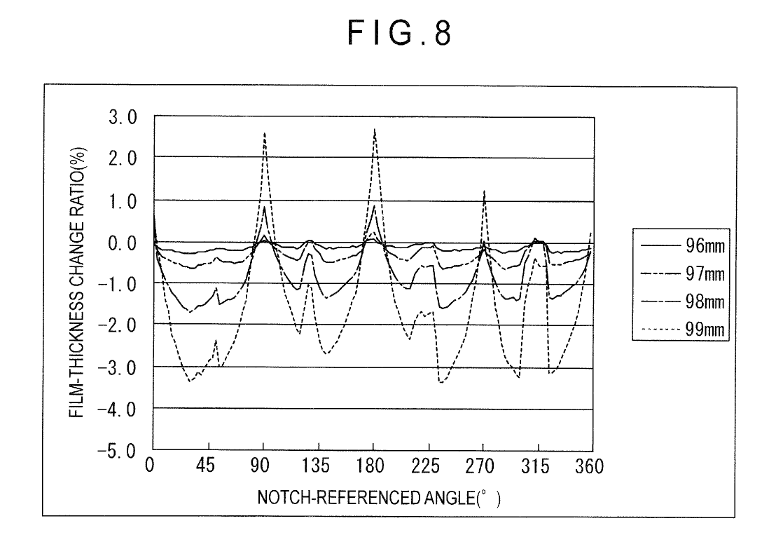

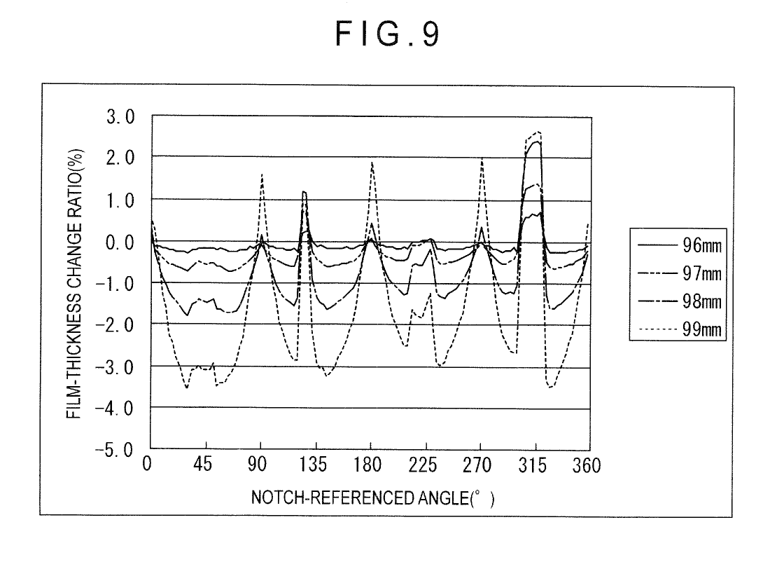

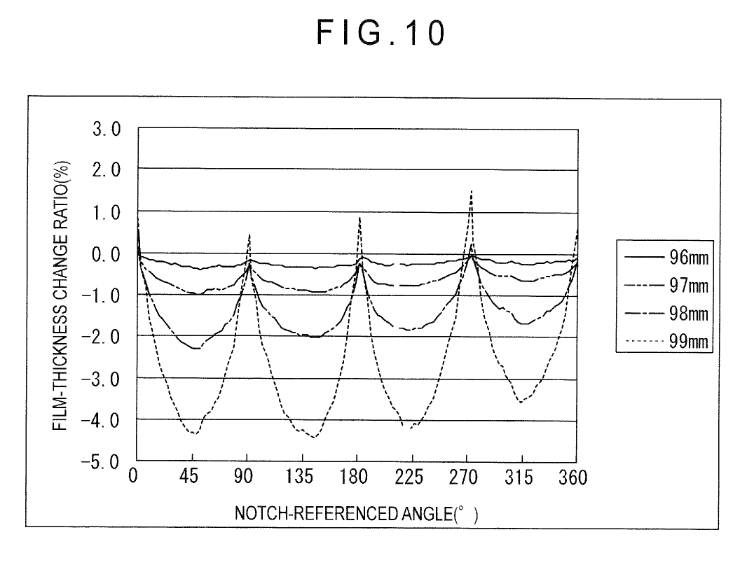

FIG. 3 is a top view of susceptors 500, 510, and 520 in Examples 1, 2, and 3 used for experiments to show function of the manufacturing apparatus 1 of an epitaxial wafer EPW. FIG. 4 shows the first wafer edge WE₁₀ and a film-thickness distribution of an epitaxial film EP in a case of an epitaxial wafer EPW manufactured using the susceptor 500 in Example 1. FIG. 5 is a top view of a susceptor 700 in Comparative Example used in experiments to describe function of the manufacturing apparatus 1 of an epitaxial wafer EPW. FIG. 6 shows the first wafer edge WE₁₀ and a film-thickness distribution of an epitaxial film EP in a case of an epitaxial wafer EPW manufactured using the susceptor 700 in Comparative Example. FIG. 7 is a graph showing a film-thickness change ratio at a variety of notch-referenced angles of an epitaxial wafer EPW manufactured using the susceptor 500 in Example 1. FIG. 8 is a graph showing a film-thickness change ratio at a variety of notch-referenced angles of an epitaxial wafer EPW manufactured using the susceptor 510 in Example 2. FIG. 9 is a graph showing a film-thickness change ratio at a variety of notch-referenced angles of an epitaxial wafer EPW manufactured using the susceptor 520 in Example 3. FIG. 10 is a graph showing a film-thickness change ratio at a variety of notch-referenced angles of an epitaxial wafer EPW manufactured using the susceptor 700 in Comparative Example.

To begin with, arrangements of susceptors 500, 510, and 520 in Examples 1, 2, and 3 used for experiments to describe function of the manufacturing apparatus 1 of an epitaxial wafer EPW will be described.

The susceptors 500-510, 520 in Examples 1, 2, and 3 are arranged similarly to the susceptor 2 according to the present invention, including the wafer placement 21 and the peripheral portions 509, 512, and 522, as shown in FIG. 3.

At least inner circumferences 502A, 512A, and 522A and upper surfaces 502B, 512B, and 522B of the peripheral portions 502, 512, and 522 have a SiC film coated thereon. Fitting grooves 502D, 512D, and 522D are formed at portions of the inner circumference of the peripheral portions 502, 512, and 522 where notch-opposition-referenced angles with reference to notch-opposing portions 502C, 512C, and 522C are 45°, 135°, 225°, and 315°. The fitting grooves 502D, 512D, and 522D are arc-shaped in plan view. A substantially central portion relative to an arc direction of each of the fitting grooves 502D, 512D, and 522D is located near each of the above-mentioned portions of the inner circumference of the peripheral portions 50), 512, and 522.

The fitting groove 502D is shaped to have a width L of 2 mm and an angle è of 45°. The fitting groove 512D is shaped to have a width L of 2 mm and an angle è of 20°. The fitting groove 522D is shaped to have a width L of 5 mm and an angle è of 20°.

CVD control units 503, 513, and 523 are attached to the fitting grooves 502D, 512D, and 522D. The CVD control units 503, 513, and 523 are members made of SiO₂ and are substantially arc-shaped in plan view corresponding to the shapes of the fitting grooves 502D, 512D, and 522D.

Next, a formation process of an epitaxial film EP of an epitaxial wafer EPW manufactured using the susceptor 500 in Example 1 will be described. Note that formation processes of epitaxial films EP manufactured using the susceptors 510 and 520 in Examples 2 and 3 are similar to the case with the susceptor 500 in Example 1 and therefore description thereof is omitted.

A substrate wafer W having a first wafer edge WE₁₀ at locations where the notch-referenced angles are 45°, 135°, 225°, and 315° and a second wafer edge WE₁₁ at locations where the notch-referenced angles are 0°, 90°, 180°, and 270° is placed on the susceptor 500 in Example 1 in the placement-determined state. When the epitaxial film EP is vapor deposited on the substrate wafer W to manufacture the epitaxial wafer EPW, since the vicinity of the second water edge WE₁₁, for example, where the notch-referenced angle is 90° is adjacent not to the CVD control unit 503 but to the upper surface 502B of the periphery on which SiC film is coated, a relatively large portion of reaction gas (hereafter referred to as periphery-supplied reaction gas G1, also see, FIG. 4) delivered toward the upper surface 502B of the peripheral portion 502 reacts with the upper surface 502B and therefore does not flow toward the substrate wafer W. Besides, a reaction gas G2 (hereafter referred to as the wafer-supplied reaction gas G2, also see, FIG. 4) supplied toward the substrate wafer W is delivered toward the substrate wafer W.

The periphery-delivered gas G1 does not reach the second wafer edge WE₁₁, but only the wafer-delivered reaction gas G2 reaches the second wafer edge WE₁₁. Consequently, chemical vapor deposition rate (hereafter abbreviated to CVD rate) of the epitaxial film EP at a bevel portion of the second wafer edge WE₁₁ is a predetermined rate, and absorption at the bevel portion is a predetermined amount. Accordingly, film-thickness distribution at the outer surface of the second wafer edge WE₁₁ is substantially even.

On the other hand, a portion of the first wafer edge WE₁₀ where the notch-referenced angle is 45°, for example, is adjacent to the CVD control unit 503 made of SiO₂ which is less reactive to the periphery-delivered reaction gas G1 than SiC. As shown in FIG. 4, the periphery-delivered gas G1 delivered toward the CVD control unit 503 is partially flowed toward the first wafer edge WE₁₀ without reacting with the CVD control unit 503. In addition, the wafer-delivered reaction gas G2 is delivered to the substrate wafer W.

The periphery-delivered reaction gas G1 and the wafer-delivered reaction gas G2 reach the first wafer edge WE₁₀. Thus, the CVD rate of the epitaxial film EP at the bevel portion WE₁₀₁ of the first wafer edge WE₁₀ is faster than the CVD rate in the case where only the wafer-delivered reaction gas G2 reaches the first wafer edge WE₁₀. Accordingly, the absorption at the bevel portion WE₁₀₁ is reduced. As a result, film-thickness of a peripheral portion of the outer surface WE₁₀₂ of the first wafer edge WE₁₀ is thicker than the case without the CVD control unit 503.

Furthermore, as described below, when only the wafer-delivered reaction gas G2 reaches the first wafer edge WE₁₀, the CVD rate at the bevel portion WE₁₀₁ is slower than the CVD rate in the case when only the wafer-delivered reaction gas G2 reaches the second wafer edge WE₁₁. Accordingly, a film-thickness of the outer surface WE₁₀₂ gradually decreases toward the peripheral portion.

From what has been set forth above, the film-thickness distribution at the outer surface WE₁₀₂ of the first wafer edge WE₁₀ is substantially even, compared to the case where the CVD control unit 503 is not provided and the periphery-delivered reaction gas G1 does not reach the first wafer edge WF₁₀.

Next, an arrangement of the susceptor 700 in Comparative Example used for experiments to show the function of the manufacturing apparatus 1 of the epitaxial wafer EPW will be described.

As shown in FIG. 5, the susceptor 700 in Comparative Example includes the wafer placement 21 and a peripheral portion 702.

At least the inner circumference 702A and the upper surface 702B of the peripheral portion 702 are coated by a SiC film.

The peripheral portion 702 is shaped such that a height of the upper surface 702B relative to the placement surface 21A of the wafer placement 21 is the same as heights of the upper surfaces 502B, 512B, and 522B of the peripheral portions 502, 512, and 522 relative to the placement surface 211A of the wafer placement 21 on the susceptors 500, 510, and 520 in Examples 1, 2, and 3.

The substrate wafer W is placed on the peripheral portion 702 in the placement-determined state, that is, the state in which the notch Wd faces the notch-opposing portion 702C.

Next, a formation process of an epitaxial film EP of an epitaxial wafer EPW manufactured with the susceptor 700 in Comparative Example will be described.

When an epitaxial wafer EPW is manufactured with the susceptor 700 in Comparative Example in the same manner as the susceptor 500 in Example 1, an upper surface 702B of the peripheral portion 702 near the second wafer edge WE₁₁ of the substrate is positioned relative to the wafer placement 21 in the same fashion as the peripheral portion 502 is positioned relative to the wafer placement 21. Accordingly, though not shown in the figures, the periphery-delivered reaction gas G1 and the wafer-delivered reaction gas G2 are respectively delivered toward the upper surface 702B and the substrate wafer W, similarly to the case where the susceptor 500 in Example 1 is employed. Therefore, the film-thickness distribution at the outer surface of the second wafer edge WE₁₁ is substantially even.

In addition, the upper surface 702B also resides near the first wafer edge WE₁₀ of the substrate wafer W. Accordingly, as shown in FIG. 6, the periphery-delivered reaction gas G1 is delivered to the upper surface 702B and the wafer-delivered reaction gas G2 is respectively delivered to the substrate wafer W.

Furthermore, the CVD rate of the epitaxial film EP at the bevel portion WE₁₀₁ of the first wafer edge WE₁₀ is faster than the rate at the bevel portion of the second wafer edge WE₁₁. Accordingly the absorption at the bevel portion WE₁₀₁ is increased. As a result, a film-thickness of the outer surface WE₁₀₂ gradually decreases toward the peripheral portion. Therefore, the film-thickness distribution becomes uneven.

Epitaxial wafers EPW were manufactured under the same condition using the susceptors 500, 510, and 520 in Examples 1, 2, and 3 and the susceptor 700 in Comparative Example. Film-thickness change ratios of the epitaxial wafers EPW at a variety of the notch-referenced angles were compared.

As shown in FIGS. 7, 8, and 9, when epitaxial wafers EPW manufactured with the susceptors 500, 510, and 520 in Examples 1, 2, and 3 were observed, the first wafer edge WE₁₀ where the notch-referenced angles of 45°, 135°, 225°, and 315° had a film-thickness change ratio of approximately −3.5% or larger at the position of 99 mm. In particular, when the susceptor 500 in Example 1 was employed, the film-thickness ratio was approximately −2.5% or larger at the position of 99 mm and the film-thickness was the most evenly distributed.

On the other hand, when the epitaxial wafer EPW was manufactured with the susceptor 700 in Comparative Example, as shown in FIG. 10, the film-thickness change ratio at the first wafer edge WE₁₀ is approximately −4.4% or lager at the position of 99 mm and the film-thickness distribution is uneven, compared to the cases employing susceptors 500, 510, and 520 in Examples 1, 2, and 3.

(Effects of Manufacturing Apparatus of Epitaxial Wafer)

The following effects are attained according to the first embodiment.

(1) The CVD control units 23 for controlling the CVD rate of the epitaxial film EP at the wafer edge WE of the substrate wafer W placed on the wafer placement 21 are provided to four portions of the peripheral portion 22 provided to the peripheral portion of the wafer placement 21 of the manufacturing apparatus 1.

Thus, the CVD rate at the wafer edge WE of the substrate wafer W near the CVD control unit 23 is controlled to be different from the other portions. Accordingly, the film-thickness distribution in the peripheral direction at the outer surface of the wafer edge WE near the CVD control unit 23 can be different from a film-thickness distribution of the case without the CVD control unit 23.

As a result, the film-thickness distribution at the outer surface is, irrespective of the crystal orientation thereof substantially even. Therefore, the unevenness of the film-thickness at the outer surface can be reduced.

(2) The peripheral portion 22 includes the inner circumference 22A standing in a fashion surrounding the wafer placement 21 and the upper surface 22B outwardly projecting in parallel to the placement surface 21A of the wafer placement 21 from the upper end of the inner circumference 22A. Moreover, in the CVD control unit 23, the inner circumference 23A coincides with the inner circumference 22A of the peripheral portion 22, and the upper surface 23B is leveled with the upper surface 22B of the peripheral portion 22. The CVD control unit 23 is made of SiO₂ which is less reactive with a reaction gas than a SiC film.

Thus, as set forth above, flow of the reaction gas can be controlled by the CVD control unit 23. Accordingly, the CVD rate at the bevel portion WE₁₀₁ at the first wafer edge WE₁₀ located near the CVD control unit 23 is faster than the case without the CVD control unit 23. As a result, the film-thickness at the outer surface WE₁₀₂ of the first wafer edge WE₁₀ can be controlled to be thicker than the case without the CVD control unit 23. Therefore, by only forming the CVD control unit 23 from SiO₂ that is less reactive with a reaction gas, the film-thickness distribution at the outer surface can be made, irrespective of the crystal orientation, substantially even. Therefore, the unevenness in the film-thickness at the outer surface can be reduced.

(3) The CVD control unit 23 is a member made of SiO₂ provided to the peripheral portion 22.

Accordingly, the durability of the substrate wafer W in the etching process can be improved compared to an arrangement in which the CVD control unit 23 is formed as a thin film.

Therefore, the CVD control unit 23 in the embodiment can be used for a longer time than the CVD control unit 23 formed as a thin film.

(4) The CVD control unit 23 is provided opposite to the first wafer edge WE₁₀ of the substrate wafer W placed on the wafer placement 21 in the placement-determined state.

Since the CVD control unit 23 is provided opposite to the first wafer edge WE₁₀ of the substrate wafer W, the unevenness in the film-thickness of the outer surface on account of crystal orientation is reduced.

(5) The manufacturing apparatus 1 of the epitaxial wafer EPW employs the susceptor 2 with the functions and effects set forth above.

Accordingly, the manufacturing apparatus 1 capable of manufacturing the epitaxial water EPW with reduced unevenness in the film-thickness at the outer surface can be provided.

(6) The wafer placement 21 has the ventilation apertures 21C.

Accordingly, when the substrate wafer W is placed on the wafer placement 21, air between the substrate wafer W and the wafer placement 21 can be discharged tinder the wafer placement 21 via the ventilation aperture 21C.

Therefore, slippage of the substrate wafer W due to air between the substrate wafer W and the wafer placement 21 can be restrained. Incidentally, similar functions and effects can be attained if the ventilation apertures 21D or 21E are provided.

(7) The axes of the ventilation apertures 21C intersect with the vertical direction.

Accordingly, the substrate wafer W is guarded from direct irradiation of light from the heater 4, so that so-called nano-topography and deterioration of film-thickness distribution can be restrained. Incidentally, similar effects can be attained if the ventilation apertures 21D are provided.

### Second Embodiment

A second embodiment of the present invention will be described below with reference to the drawings.

Hereafter, the same structures and the same members as the first embodiment will be provided with the same numerals, and description thereof will be omitted or simplified.

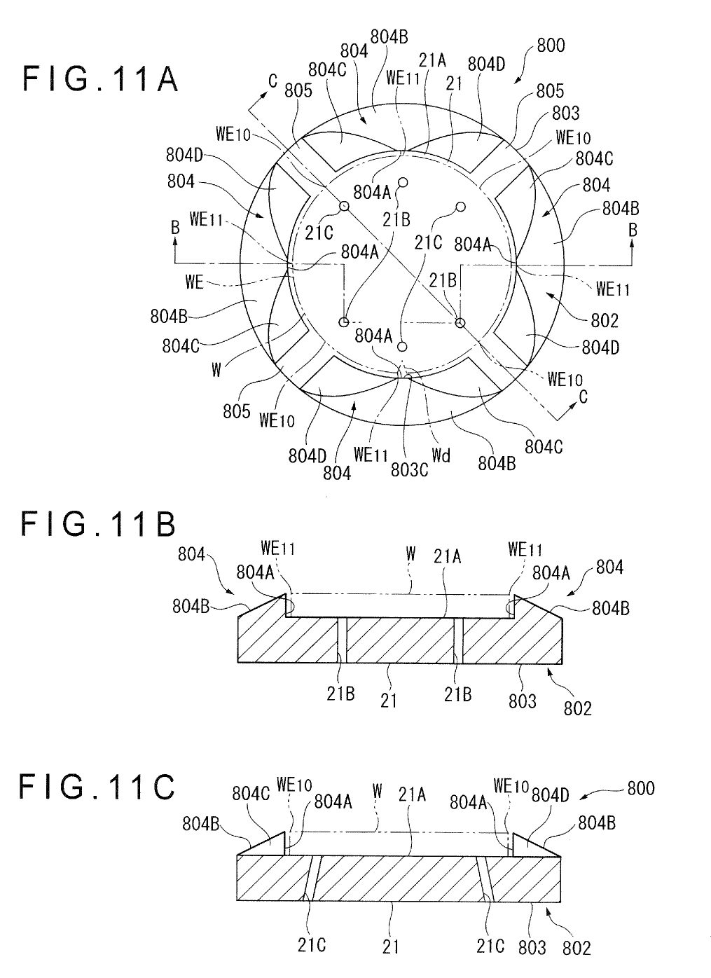

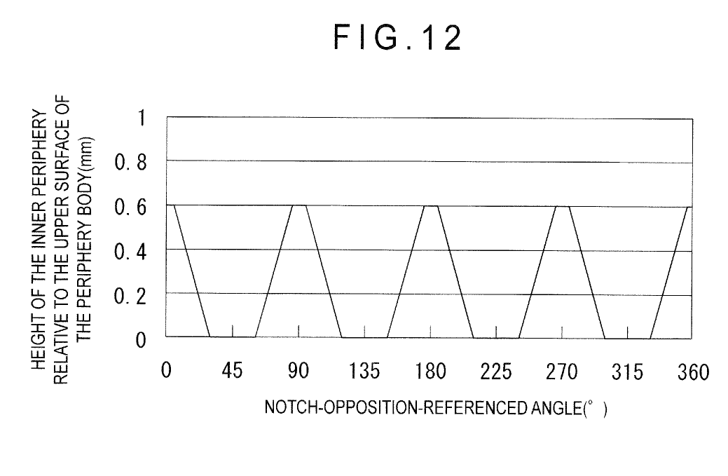

FIGS. 11A to 11C schematically show an arrangement of the susceptor 800 according to the second embodiment. FIG. 11A is a top view of the susceptor 800. FIG. 11B is a cross-sectional view taken along B-B line in FIG. 11A. FIG. 11C is a cross-sectional view taken along C-C line in FIG. 11A. FIG. 12 shows a height of an inner periphery relative to an upper surface of the periphery body at a variety of the notch-opposition-referenced angles.

(Arrangement of Susceptor)

As shown in FIGS. 11A, 11B, and 11C, the susceptor 800 integrally includes the wafer placement 21 and the peripheral portion 802 formed substantially in a ring-plate shape surrounding the peripheral portion of the wafer placement 21.

The peripheral portion 802 includes a periphery body 803 formed substantially in a ring-plate shape having am upper surface being leveled with the placement surface 21A of the wafer placement 21. In the periphery body 803, a projection 804 projecting upward is integrally provided to portions where the notch-opposition-referenced angles with reference to a notch-opposing portion 803C are 60° to 120°, 150° to 210°, 240° to 300°, and 330° to 30°. The projections 804 are substantially arc-shaped in plan view and are substantially quadrangular-pyramid shaped. In other words, the projection 804 is formed opposite to the second wafer edge WE₁₁ of the substrate wafer W placed in the placement-determined state.

The projection 804 includes: an inner lateral surface 804A having a substantially trapezoid shape whose lower side is longer than the upper side and standing in a direction substantially perpendicular to the placement surface 21A of the wafer placement 21; an outer lateral surface 804B having a substantially trapezoid shape which shares the upper side with the inner lateral surface 804A and has a lower side longer than the upper side; a right lateral surface 804C having a substantially triangular shape which shares the oblique sides with the inner lateral surface 804A and the outer lateral surface 804B; and the left lateral surface 804D having substantially the same shape as the right lateral surface 804C. As shown in FIG. 12, the upper side of the substantially trapezoid shape of the inner lateral surface 804A is located at the portions where the notch-opposition-referenced angles are 85° to 95°, 175° to 185°, 265° to 275°, and 355° to 5°. A height of the substantially trapezoid shape of the inner lateral surface 804A relative to the upper surface of the periphery body 803 is 0.6 mm. The height of this substantially trapezoid shape may be determined within a range of 0.7 to 1.3 times as thick as the substrate wafer W.

Further, the portions of the periphery body 803 where the notch-opposition-referenced angles are 30° to 60°, 120° to 150°, 210° to 240°, and 300° and 330° have upper surfaces that are lower than the upper end of the projection 804, which can also be called the upper end of the peripheral portion 802, and form the CVD control unit 805. The CVD control unit 805 is configured such that an end of the substrate wafer W is exposed when the substrate wafer W is placed on the wafer placement 21.

A SiC film is coated on the projection 804 and the CVD control unit 805.

(Effects of Manufacturing Apparatus of Epitaxial Wafer)

According to the second embodiment, the following function and effect can be attained in addition to the functions and effects (1) and (4) to (7) of the first embodiment.

(8) The peripheral portion 802 is provided with a CVD control unit 805. The CVD control unit 805 has an upper surface that is lower than the upper end of the periphery body 803, and is configured such that an end of the substrate wafer W is exposed when the substrate wafer W is placed on the wafer placement 21.

Accordingly, more reaction gas is delivered to the CVD control unit 805 of the peripheral portion 802 and flowed toward the wafer edge WE than is delivered to the projection 804 and flowed toward the wafer edge WE.

Thus, the CVD rate at the bevel portion of the first wafer edge WE₁₀ located near the CVD control unit 805 can be faster than the CVD rate at the bevel portion of the second wafer edge WE₁₁ located near the projection 804 to reduce absorption at the bevel portion. Consequently, the film-thickness at the outer surface of the first wafer edge WE₁₀ can be controlled to be thicker than the second wafer edge WE₁₁. Therefore, the film-thickness distribution at the outer surface is, irrespective of crystal orientation, substantially even, so that unevenness in the film-thickness at the outer surface can be reduced.

### Third Embodiment

A third embodiment of the present invention will be described below with reference to the drawings.

Hereafter, the same structures and the same members as the first embodiment will be provided with the same numerals, and description thereof will be omitted or simplified.

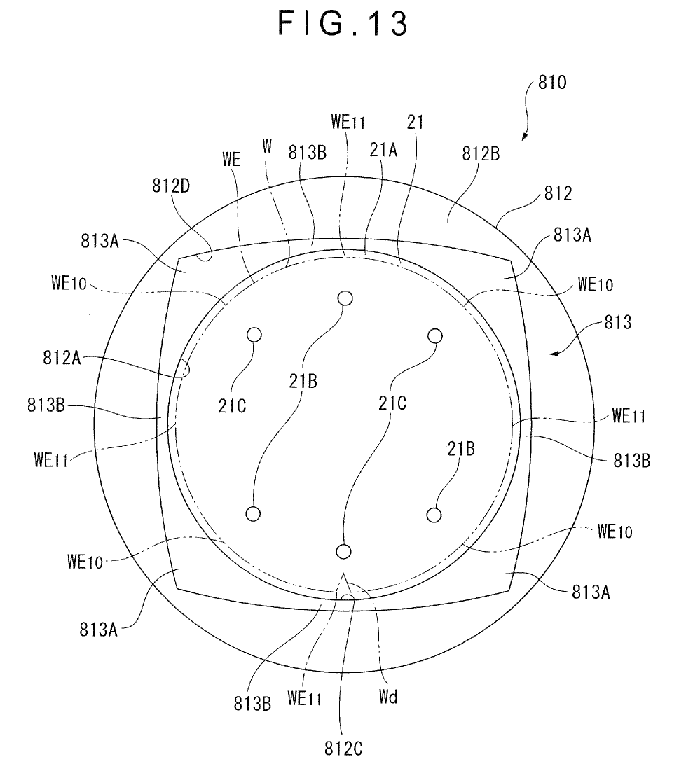

FIG. 13 is a top view schematically showing a susceptor 810 according to the third embodiment.

(Arrangement of Susceptor)

As shown in FIG. 13, the susceptor 810 includes the wafer placement 21 and a peripheral portion 812. The peripheral portion 812 is substantially in a ring-plate shape and includes: an inner circumference 812A standing in a fashion surrounding a peripheral portion of the wafer placement 21; and an upper surface 812B outwardly extending from an upper end of the inner circumference 812A in parallel to the placement surface 21A of the wafer placement 21.

At least the inner circumference 812A and the upper surface 812B of the peripheral portion 812 are coated by, for example, a SiC film. In addition, the fitting groove 812D is formed substantially ring-shaped along an inner periphery of the peripheral portion 812 along the inner periphery of the upper surface 812B of the peripheral portion 812.

Externally, the fitting groove 812D has a substantially squared shape in plan view, whose corners are located at the portions where the notch-opposition-referenced angles with reference to the notch-opposing portion 812C are 45°, 135°, 225°, and 315°. In other words, the fitting groove 812D is shaped such that lengths in the planar direction at the portions where the notch-opposition-referenced angles are 45°, 135°, 225°, and 315° are longer than the other portions.

A CVD control unit 813 formed as a substantially ring shaped member made of SiO₂ is attached to the fitting groove 812D.

The CVD control unit 813 includes four wide sections 813A and narrow sections 813B. The wide sections 813A are located at the portions where the notch-opposition-referenced angles are 45°, 135°, 225°, and 315° and are substantially shaped as isosceles triangles in plan view, respectively having an apex outwardly located relative to the center of placement of the substrate wafer of the wafer placement 21. Each of the narrow sections 813B is adjacent to the wide section 813A and has a smaller dimension than the wide section 813A in a direction from the center of placement of the substrate wafer to the outside.

In other words, the CVD control unit 813 includes the wide section 813A and the narrow section 813B shorter in the planar direction than the wide section 813A, where the wide section 813A is provided opposite to the first wafer edge WE₁₀ of the substrate wafer W placed in the placement-determined state.

(Effects of Manufacturing Apparatus of Epitaxial Wafer)

According to the third embodiment, the following function and effect can be attained in addition to the functions and effects (1) to (7) of the first embodiment.

(9) The peripheral portion 812 is provided with the CVD control unit 813 made of SiO₂ having a substantially ring-plate shape that provides alternate arrangement of the wide section 813A and the narrow section 813B.

Accordingly, more gas is delivered to the wide section 813A and flowed toward the wafer edge WE than is delivered to the narrow section 813B, which is shorter in the planar direction than the wide section 813A, and flowed toward the wafer edge WE.

Thus, the CVD rate at the bevel portion of the first wafer edge WE₁₀ located near the wide section 813A can be controlled to be faster than the CVD rate at the bevel portion of the second wafer edge WE₁₁ located near the narrow section 813B to reduce absorption at the bevel portion. Consequently, the film-thickness at the outer surface of the first wafer edge WE₁₀ can be controlled to be thicker than the second wafer edge WE₁₁. Therefore, the film-thickness distribution at the outer surface is, irrespective of crystal orientation, substantially even, so that the unevenness of the film-thickness at the outer surface can be reduced.

### Fourth Embodiment

A fourth embodiment of the present invention will be described below with reference to the drawings.

Hereafter, the same structures and the same members as the first embodiment will be provided with the same numerals, and description thereof will be omitted or simplified.

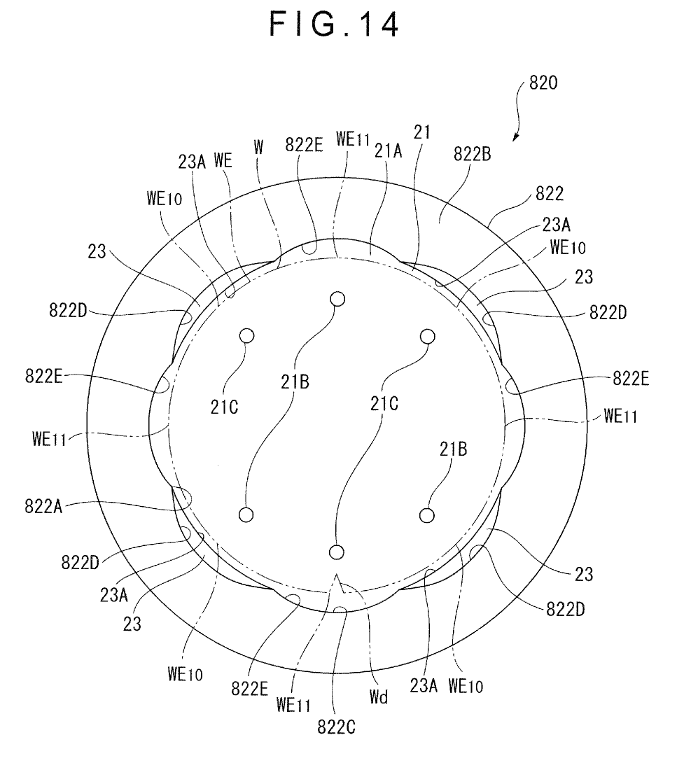

FIG. 14 is a top view schematically showing a susceptor 820 according to the fourth embodiment.

(Arrangement of Susceptor)

As shown in FIG. 14, the susceptor 820 includes the wafer placement 21 and a peripheral portion 822. The peripheral portion 822 is substantially in a ring-plate shape and includes: an inner circumference 822A standing in a fashion surrounding a peripheral portion of the wafer placement 21; and an upper surface 822B outwardly extending from an upper end of the inner circumference 822A in parallel to the placement surface 21A of the wafer placement 21.

Dents 822E are formed on the inner periphery of the peripheral portion 822 in a substantially falcate shape in plan view. The substantially central portion of the dents 822E with respect to an arc direction is located at the portions where the notch-opposition-referenced angles with reference to the notch-opposing portion 822C are 0°, 90°, 180°, and 270°. In other words, the distance from the portions of the inner circumference 822A where the notch-opposition-referenced angles are 0°, 90°, 180°, and 270° to the center of the wafer placement 21 is longer than the distance in the cases where the angles are 45°, 135°, 225°, and 315°.

At least the inner circumference 822A and the upper surface 822B of the peripheral portion 822 are coated by, for example, a SiC film. Furthermore, a fitting groove having substantially the same shape as the fitting groove 22D in the first embodiment is formed on the upper surface of the peripheral portion 822.

The CVD control unit 23 is attached to the fitting groove 822D. In other words, the CVD control unit 23 is attached in a manner that the inner circumference 23A thereof projects toward the placement center of the wafer placement 21 with respect to the inner circumference 822A of the peripheral portion 822

(Effects of Manufacturing Apparatus of Epitaxial Wafer)

According to the fourth embodiment, the following function and effect can be attained in addition to the functions and effects (1) to (7) of the first embodiment.

(10) The CVD control unit 23 is provided in a manner that the inner circumference 23A thereof projects toward the placement center of the wafer placement 21 with respect to the inner circumference 822A of the peripheral portion 822.

Accordingly, when the substrate wafer W is placed in the placement-determined position, the portion where the CVD control unit 23 is provided is closer to the vicinity of the wafer edge WE than the portion where the CVD control unit 23 is not provided.

Consequently, as compared to the arrangement in the first embodiment in which a distance between the inner periphery of the portion of the periphery where the CVD control unit 23 is provided and the center of the wafer placement 21 is the same as distances between the inner peripheries of other portions of the periphery and the center of the wafer placement 21 (the susceptor 2 in the first embodiment), the reaction gas that is delivered to the CVD control unit 23 and flowed toward the wafer edge WE can be more securely delivered to the wafer edge WE. Therefore, unevenness in the film-thickness at the outer surface can be efficiently reduced.

### Fifth Embodiment

A fifth embodiment of the present invention will be described below with reference to the drawings.

Hereafter, the same structures and the same members as the first embodiment will be provided with the same numerals, and description thereof will be omitted or simplified.

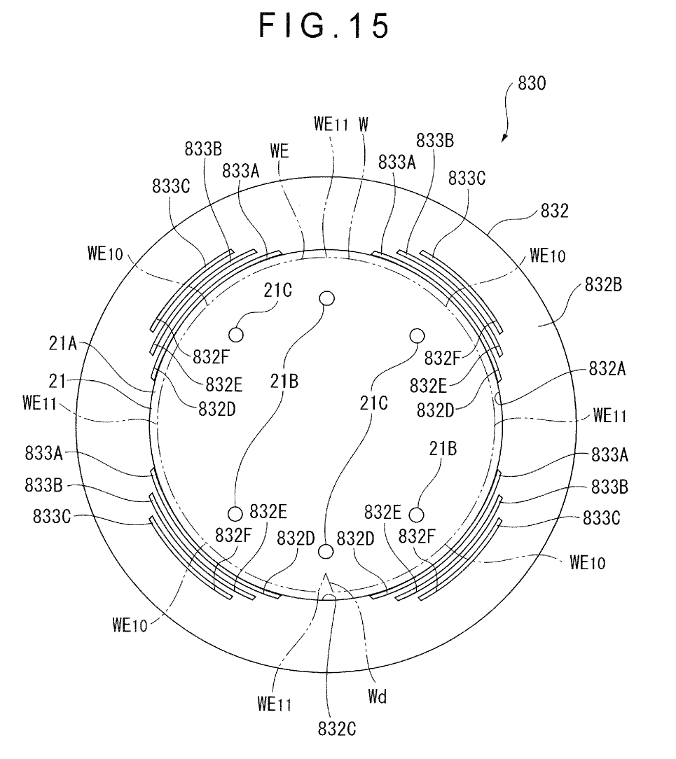

FIG. 15 is a top view schematically showing a susceptor 830 according to the fifth embodiment.

(Arrangement of Susceptor)

As shown in FIG. 15, the susceptor 830 includes the wafer placement 21 and a peripheral portion 832. The peripheral portion 832 is substantially in a ring-plate shape and includes: an inner circumference 832A standing in a fashion surrounding a periphery of the wafer placement 21; and an upper surface 832B outwardly extending from an upper end of the inner circumference 832A in parallel to the placement surface 21A of the wafer placement 21.

At least the inner circumference 832A and the upper surface 832B of the peripheral portion 832 are coated by, for example, a SiC film. Fitting grooves 832D, 832E, and 832F, arc slit-shaped in plan view, are provided to an inner periphery of the peripheral portion 832. The substantially central portion of each of the fitting grooves 832D, 832E, and 832F with respect to an arc direction is located at the portion where the notch-opposition-referenced-angle with reference to a notch-opposing portion 835C is 45°. The fitting grooves 832D, 832E, and 832F are sequentially formed in a radially outward direction with predetermined intervals. Of the fitting grooves 832D, 832E, and 832F ones that are disposed more radially outwardly have smaller arc-lengths. In addition, the fitting grooves 832D, 832E, and 832F are formed at the portions of the peripheral portion 832 where the notch-opposition-referenced angles are 135°, 225°, and 315°.

Vapor deposition control units 833A, 833B, and 833C that are members made of SiO₂ and substantially arc slit-shaped in plan view are attached to the fitting grooves 832D, to 832E, and 832F. In other words, the CVD control units 833A, 833B, and 833C are attached in such manner that SiO2 is exposed in a discrete pattern.

Incidentally, a discrete pattern of the exposure of the CVD control units 833A, 833B, and 833C may be any other suitable discrete pattern such as a dotted pattern in plan view or the like.

(Effects of Manufacturing Apparatus of Epitaxial Wafer)

According to the fifth embodiment, the following function and effect can be attained in addition to the functions and effects (2) to (7) of the first embodiment.

(11) The CVD control units 833A, 833B, and 833C are provided in such manner that SiO₂ is exposed in a discrete pattern.

Accordingly, advantages can be attained compared to a CVD control unit 23 exposed in a continuous pattern such as the CVD control unit 23 in the first embodiment. For example, if a silicon film is formed on the CVD control unit 833A, accompanying formation of silicon films on the CVD control units 833B and 833C can be restrained.

Therefore, compared to an arrangement in which the CVD control unit 23 is exposed in a continuous pattern, the CVD control unit can be used for a longer time without, for example, removal process of the silicon film.

### Sixth Embodiment

Next, a sixth embodiment of the present invention will be described below with reference to the drawings.

Hereafter, the same structures and the same members as the first embodiment will be provided with the same numerals, and description thereof will be omitted or simplified.

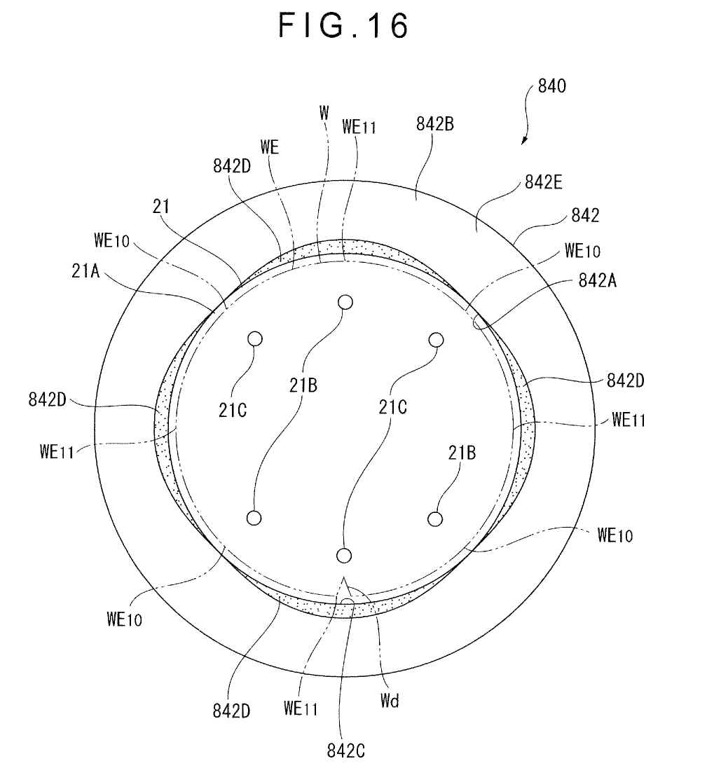

FIG. 16 is a top view schematically showing a susceptor 840 according to the sixth embodiment.

(Arrangement of Susceptor)

As shown in FIG. 16, the susceptor 840 includes the wafer placement 21 and a peripheral portion 842. The peripheral portion 842 is substantially in a ring-plate shape and includes: an inner circumference 842A standing in a fashion surrounding a peripheral portion of the wafer placement 21; and an upper surface 842B outwardly extending from an upper end of the inner circumference 842A in parallel to the placement surface 21A of the wafer placement 21.

At least the inner circumference 842A and the upper surface 842B of the peripheral portion 842 are coated by, for example, a SiC film.

A low-flatness section 842D is provided to an upper surface 842B of the peripheral portion 842. The low-flatness section 842D is substantially falcate in plan view and exhibits a larger surface area per unit region than other portions. A substantially central portion of the low-flatness section 842D with respect to an arc direction is located at the portions where the notch-opposition-referenced angles with reference a notch-opposing portion 842C are 0°, 90°, 180°, and 270°. In other words, the low-flatness section 842D is provided opposite to the second wafer edge WE₁₁ of the substrate wafer W placed in the placement-determined state. A portion of an upper surface 842B excluding the low-flatness section 842D forms high-flatness section 842E.

Here, the low-flatness section 842D and the high-flatness section 842E may be provided by, for example, adding a member to the peripheral portion 842 or scraping the peripheral portion 842 so that a surface area per unit region is increased in the low-flatness section 842D. The low-flatness section 842D and the high-flatness section 842E may be provided also by adding a member to the peripheral portion 842 or mirror-finishing the peripheral portion 842 into a mirror-like state so that a surface area per unit region is decreased in the high-flatness section 842E.

(Effects of Manufacturing Apparatus of Epitaxial Wafer)

According to the sixth embodiment, the following function and effect can be attained in addition to the functions and effects (1) and (4) to (7) of the first embodiment.

(12) The peripheral portion 842 is provided with the low-flatness section 842D in which a surface area per unit region in plan view is large.

Accordingly, a reaction gas is more likely to be adsorbed to the low-flatness section 842D than to the high-flatness section 842E. As a result, more reaction gas is delivered to the high-flatness section 842F and flowed toward the wafer edge WE than is delivered to the low-flatness section 842D and flowed toward the wafer edge WE.

Thus, the CVD rate at the bevel portion of the first wafer edge WE₁₀ located near the high-flatness section 842E can be controlled to be faster than the CVD rate at the bevel portion of the second wafer edge WE₁₁ located near the low-flatness section 842D to reduce absorption at the bevel portion. Consequently, the film-thickness at the outer surface of the first wafer edge WE₁₀ can be controlled to be thicker than that of the second wafer edge WE₁₁. Therefore, the film-thickness distribution at the outer surface is, irrespective of crystal orientation, substantially even, so that the unevenness of the film-thickness at the outer surface can be reduced.

### Seventh Embodiment

A seventh embodiment of the present invention will be described below with reference to the drawings.

Hereafter, the same structures and the same members as the first embodiment will be provided with the same numerals, and description thereof will be omitted or simplified.

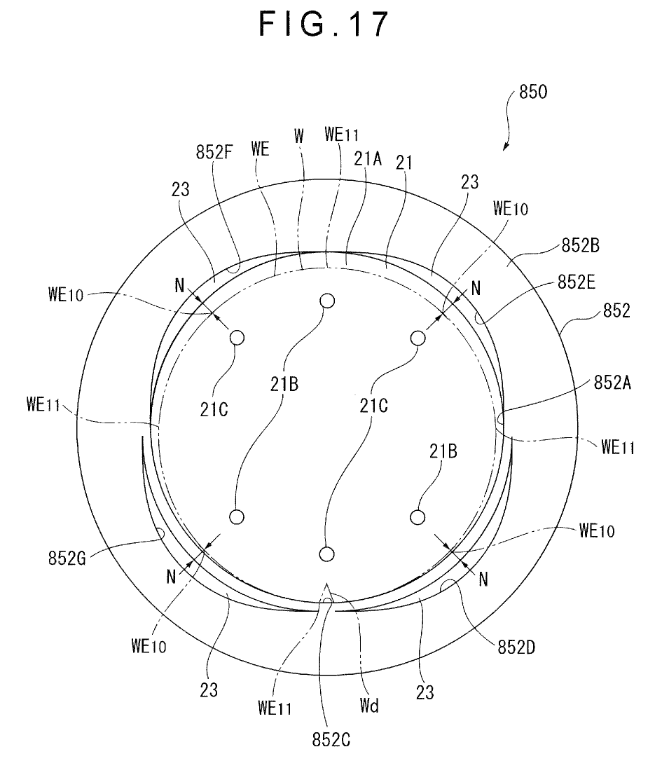

FIG. 17 is a top view schematically showing a susceptor 850 according to the seventh embodiment.

(Arrangement of Susceptor)

As shown in FIG. 17, the susceptor 850 includes the wafer placement 21 and a peripheral portion 852. The peripheral portion 852 is substantially in a ring-plate shape and includes: an inner circumference 852A standing in a fashion surrounding a peripheral portion of the wafer placement 21; and an upper surface 852B outwardly extending from an upper end of the inner circumference 852A in parallel to the placement surface 21A of the wafer placement 21.

The substrate wafer W is placed on the wafer placement 21 in such manner that a notch Wd constantly faces toward a predetermined direction and an outer periphery of the substrate wafer W near the notch Wd abuts to the inner circumference 852A of the peripheral portion 852. In other words, the substrate wafer W is placed on the wafer placement 21 in such manner that the center of the substrate wafer is misaligned with the center of the wafer placement 21 (hereafter referred to as the center-misaligned state).

A method to place the substrate wafer W in the center-misaligned state may be exemplified as follows. The placement surface 21A of the wafer placement 21 is inclined, or a wafer hand or a lift pin used for a conveying jig is inclined so that the substrate wafer W can be slid toward the notch Wd to be placed there.

At least the inner circumference 852A and the upper surface 852B of the peripheral portion 852 are coated by, for example, a SiC film. Fitting grooves 852D, 852E, 852F, and 852G having substantially the same shape as the fitting groove 22D in the first embodiment are formed on portions of the peripheral portion 852 where the notch-opposition-referenced angles with reference to a notch-opposing-portion 852C are 45°, 135°, 225°, and 315°.

The fitting grooves 852D, 852E, 852F, and 852G have respectively an inner periphery substantially parallel to all outer periphery of the substrate wafer W placed in the center-misaligned state and are respectively located so that a distance N from each of the fitting grooves to the substrate wafer W is substantially the same. In other words, the fitting grooves 852D and 852G are farther apart from the peripheral portion 852 than the fitting, grooves 852E and 852F.

The CVD control unit 23 is attached to the fitting grooves 852D, 852E, 852F, and 852G.

(Effects of Manufacturing Apparatus of Epitaxial Wafer)

According to the seventh embodiment, the following function and effect can be attained in addition to the functions and effects (1) to (7) of the first embodiment.

(13) The substrate wafer W is placed on the susceptor 850 in such manner that the outer periphery of the substrate wafer W near the notch Wd abuts to the inner circumference 852A of the peripheral portion 852.

Accordingly, compared to, for example, the substrate wafer W that is placed substantially at the center of the wafer placement 21 such as one in the first embodiment, a position of the substrate wafer W can be determined with ease.

### Other Embodiments

Incidentally, the scope of the present invention is not limited to the above-mentioned embodiments, but includes a variety of improvements and configuration modifications as far as an inventive concept of the present invention is accomplished.

For instance, whereas the CVD control units 23, 813, 23, 833A to 833C, and 23 are members that are attached to the susceptors 2, 810, 820, 830, and 850 in the first, third, fourth, fifth, and seventh embodiments, the CVD control units may be provided in a form of a film on the upper surface 22B, 812B, 822B, 832B, and 852B or the inner circumferences 22A, 812A, 822A, 832A, and 852A.

In the first, fourth, fifth, and seventh embodiments, any one, two, or three of the portions where the notch-opposition-referenced angles are 45°, 135°, 225°, and 315° may be provided without the CVD control unit 23, 23, 833A to 833C, or 23.

In the third embodiment, any one, two, or three of the portions where the notch-opposition-referenced angles are 45°, 135°, 225°, and 315° may be provided without the wide sections 813A.

In the second and sixth embodiments, any one, two, or three of the portions where the notch-opposition-referenced angles are 0°, 90°, 180°, and 270° may be provided without the projection 804 or the low-flatness section 842D.

Moreover, any one, two, or three of the portions where the notch-opposition-referenced angles are 0°, 90°, 180°, and 270° may be provided with CVD control units made of a material that promotes reaction with a reaction gas.

In such an arrangement, a relatively large amount of the wafer-delivered reaction gas delivered to the wafer edge WE is flowed to the CVD control units. On the other hand, if such CVD control units are not provided, the course of the wafer-delivered reaction gas is not changed, so that the wafer-delivered reaction gas is flowed to the wafer edge WE while little of the wafer-delivered reaction gas is flowed toward the periphery.

Thus, the CVD rate of the bevel portion near the CVD control units are controlled to be slower than in the case without the CVD control units to increase absorption at the bevel portion. As a result, the film-thickness at an outer peripheral side of the outer surface near the CVD control units can be controlled to be thinner than the case without the CVD control units. Therefore, by only forming the CVD control unit from a material that promotes reaction with a reaction gas, the film-thickness distribution at the outer surface can be made, irrespective of the crystal orientation, substantially even, so that the unevenness in the film-thickness at the outer surface can be reduced.

The best mode of carrying out and of the present invention and such have been disclosed, but the present invention is not limited thereto. The present invention is described and shown in the figures chiefly on a particular embodiment, but as far as an inventive idea or an object of the present invention is achieved, the above-described embodiments may be modified in a variety of ways as to the shapes, materials, amounts, and other specific arrangements.

Accordingly, limitations on shapes and materials set forth above are exemplary disclosure for providing a more specific description of the present invention and do not limit the present invention. Therefore, the members called without a portion of or all of the disclosed limitations on shapes, materials and the like are included in the present invention.

### INDUSTRIAL APPLICABILITY

Capable of reducing unevenness in film-thickness of the epitaxial film on the outer surface of the substrate wafer, the susceptor according to the present invention is advantageous as a manufacturing apparatus of an epitaxial wafer.

1. A susceptor on which a substrate wafer is placed when an epitaxial wafer is manufactured by growing an epitaxial film by chemical vapor deposition on a surface of the substrate wafer, the susceptor comprising:
a wafer placement on which the substrate wafer is placed;
a peripheral portion provided in a fashion surrounding a periphery of the wafer placement; and
a chemical vapor deposition control unit that is provided to at least a portion of the peripheral portion and controls a chemical vapor deposition rate at a bevel portion and an outer surface of the substrate wafer placed on the wafer placement.

2. The susceptor according to claim 1, wherein
the peripheral portion comprises an inner circumference standing in a fashion surrounding the wafer placement and an upper surface outwardly extending from an upper end of the inner circumference in parallel to a placement surface of the wafer placement, and
the chemical vapor deposition control unit is provided to at least one of the inner circumference and the upper surface at the portion of the peripheral portion and made of a material that promotes or suppresses reaction with a reaction gas for growing the epitaxial film by chemical vapor deposition.

3. The susceptor according to claim 2, wherein
the chemical vapor deposition control unit comprises an inner circumference that has a curvature substantially similar to a curvature of the inner circumference of the peripheral portion and an upper surface that is leveled with the upper surface of the peripheral portion, and
at least a portion of the inner circumference of the chemical vapor deposition control unit projects toward a placement center of the wafer placement compared to other portions of the inner circumference of the peripheral portion.

4. A susceptor on which a substrate wafer is placed when an epitaxial wafer is manufactured by chemical vapor deposition of an epitaxial film on a surface of the substrate wafer, the susceptor comprising:
a wafer placement on which the substrate wafer is placed;
a peripheral portion that comprises an inner circumference standing in a fashion surrounding the wafer placement and an upper surface outwardly extending from an upper end of the inner circumference along a placement surface of the wafer placement; and
a chemical vapor deposition control unit that is formed on the peripheral portion, the chemical vapor deposition control unit comprising a wide section and a narrow section respectively having a different length from a center of the wafer placement in an outward direction, and being made of a material that promotes or suppresses reaction with a reaction gas for growing the epitaxial film by chemical vapor deposition.

5. The susceptor according to claim 2, wherein
the chemical vapor deposition control unit is formed as a member made of the material and fitted to the peripheral portion.

6. The susceptor according to claim 2, wherein
the chemical vapor deposition control unit is provided in such manner that the material that promotes or suppresses reaction with the reaction gas is exposed in a discrete pattern.

7. The susceptor according to claim 1, wherein
the chemical vapor deposition control unit is formed as a low-flatness section having a larger surface area per unit region than other portions of an upper surface of the peripheral portion.

8. The susceptor according to claim 1, wherein
the peripheral portion comprises a periphery body having an upper surface formed substantially in a ring shape that is leveled with the wafer placement and a projection projecting upward from a portion of the upper surface of the periphery body, and
the chemical vapor deposition control unit is a portion of the periphery body excluding the projection and is formed in such manner that a side of the substrate wafer is exposed when the substrate wafer is placed on the wafer placement.

9. The susceptor according to claim 1, wherein
the chemical vapor deposition control unit is provided in a manner corresponding to a crystal orientation of the substrate wafer placed on the wafer placement.

10. A manufacturing apparatus of an epitaxial wafer that manufactures an epitaxial wafer by growing an epitaxial film by chemical vapor deposition on a surface of a substrate wafer, the manufacturing apparatus comprising:
a susceptor on which the substrate wafer is placed when the epitaxial wafer is manufactured by growing an epitaxial film by chemical vapor deposition on the surface of the substrate wafer, the susceptor comprising:
a wafer placement on which the substrate wafer is placed,
a peripheral portion provided in a fashion surrounding a periphery of the wafer placement, and
a chemical vapor deposition control unit that is provided to at least a portion of the peripheral portion and controls a chemical vapor deposition rate at a bevel portion and an outer surface of the substrate wafer placed on the wafer placement;
a reaction container in which the susceptor is housed and into which a reaction gas for growing the epitaxial film by chemical vapor deposition on the surface of the substrate wafer can be delivered; and
a heater that heats substrate wafer upon growing the epitaxial film by chemical vapor deposition.

11. The susceptor according to claim 4, wherein
the chemical vapor deposition control unit is formed as a member made of the material and fitted to the peripheral portion.

12. The susceptor according to claim 4, wherein
the chemical vapor deposition control unit is provided in such manner that the material that promotes or suppresses reaction with the reaction gas is exposed in a discrete pattern.

13. The susceptor according to claim 4, wherein
the chemical vapor deposition control unit is provided in a manner corresponding to the crystal orientation of the substrate wafer placed on the wafer placement.

14. A manufacturing apparatus of an epitaxial wafer that manufactures an epitaxial wafer by growing an epitaxial film by chemical vapor deposition on a surface of a substrate wafer, the manufacturing apparatus comprising:
a susceptor on which a substrate wafer is placed when an epitaxial wafer is manufactured by growing an epitaxial film by chemical vapor deposition on a surface of the substrate wafer, the susceptor comprising:
a wafer placement on which the substrate wafer is placed,
a peripheral portion that comprises an inner circumference standing in a fashion surrounding the wafer placement and an upper surface outwardly extending from an upper end of the inner circumference along a placement surface of the wafer placement, and
a chemical vapor deposition control unit that is formed on the peripheral portion, the chemical vapor deposition control unit comprising a wide section and a narrow section respectively having a different length from a center of the wafer placement in an outward direction, and being made of a material that promotes or suppresses reaction with a reaction gas for growing the epitaxial film by chemical vapor deposition;
a reaction container in which the susceptor is housed and into which a reaction gas for growing the epitaxial film by chemical vapor deposition on the surface of the substrate wafer can be delivered; and
a heater that heats substrate wafer upon growing the epitaxial film by chemical vapor deposition.
